(19) United States
(12) Patent Application Publication
(10) Pub. No.: US 2021/0035915 A1
(43) Pub. Date: Feb. 4, 2021

(54) SEMICONDUCTOR DEVICE STRUCTURE WITH COMPOUND SEMICONDUCTOR AND METHOD FOR PRODUCING THE SAME

(71) Applicant: Fraunhofer-Gesellschaft zur Förderung der angewandten Forschung e.V., Munich (DE)

(72) Inventor: Armin KLUMPP, Munich (DE)

(21) Appl. No.: 16/942,534

(22) Filed: Jul. 29, 2020

(30) Foreign Application Priority Data
Jul. 31, 2019 (DE) 102019211465.2

(51) Int. Cl. H01L 23/538; H01L 27/06; H01L 21/768

(52) U.S. Cl. CPC H01L 23/5384; H01L 27/0688; H01L 21/76877; H01L 21/76802; H01L 23/5386

(57) ABSTRACT

The invention relates to a semiconductor structure including a substrate with a first main surface located on a first substrate side and a second main surface located on an opposite second substrate side as well as a vertical via extending completely through the substrate between the first main surface and the second main surface. On the first substrate side, a metallization layer that is connected galvanically to the via is arranged in the region of the via. A compound semiconductor layer connected galvanically to the metallization layer is arranged on the metallization layer. Further, the invention relates to a method for producing such a semiconductor device structure.

### CROSS-REFERENCE TO RELATED APPLICATIONS

This application claims priority from German Patent Application No. 102019211465.2, which was filed on Jul. 31, 2019, and is incorporated herein in its entirety by reference.

The invention relates to a semiconductor device structure having a compound semiconductor, a three-dimensional semiconductor device having such a semiconductor device structure and a method for producing such a semiconductor device structure.

### BACKGROUND OF THE INVENTION

The present invention can be used particularly advantageously in the field of 3D system integration. Three-dimensional integration is the vertical connection (mechanical and electrical) of devices produced by means of planar technology. The latter are also referred to as two-dimensional or 2D systems, since the circuit structures are arranged in a horizontal two-dimensional plane (also referred to as horizontal main substrate plane). At least two two-dimensional systems produced in conventional planar technology and arranged on top of one another can then be vertically connected to form a 3D system. Here, the vertical direction relates to the above-stated horizontal two-dimensional plane of the respective 2D system or to the device structures extending in a planar (horizontal) manner across the respective substrate, such as integrated circuits or doped regions, wherein the vertical direction essentially runs perpendicular to the horizontal plane. Accordingly, a 3D system (vertical and horizontal) can comprise at least two or more 2D systems (horizontal) arranged vertically on top of one another.

The 3D systems are mainly divided into two main groups. In so-called 3D packaging, two or more individual assemblies, such as chips or dies are stacked vertically on top of one another and are integrated in a three-dimensionally arranged package. The individual assemblies are connected to one another by means of vertical vias. Here, the circuits of the individual chips are not integrated in a single common circuit. The same still communicate outside the chip via electrical signals, as if they were mounted in different housings on a printed circuit board. In the so-called ICs (IC=integrated circuit), however, several components of a common circuit are arranged vertically on top of one another and are connected to a single common circuit by means of the vertical vias. This means a 3D IC acts like a single IC. All components on all chip levels communicate with one another within the 3D IC, depending on how the same was designed, both vertically as well as horizontally.

If, for the purpose of the present disclosure, a three-dimensional system integration, a 3D system or a three-dimensional semiconductor device and the same is discussed, this includes both of the above-stated main groups.

The advantages of a three-dimensional integrated microelectronic system are, among others, the higher packing densities and switching velocities that can be obtained with the same design rules compared two-dimensional systems produced conventionally in planar technology. These higher switching velocities are, on the one hand, due to shorter conduction paths between the individual devices or circuits and, on the other hand, due to the option of parallel information processing.

Additionally, 3D systems have the advantage that, when increasing the integration density, the footprint of the device can be kept small compared to 2D systems, since the increase of integration density results in higher space requirements in lateral (or horizontal) direction in a 2D system, while the additionally available space in a 3D system is used in vertical direction.

This can be particularly advantageous in neuromorphic or neuronal networks where extension in lateral direction is not desirable for reasons of limited space. Additionally, fast switching velocities as well as a low power consumption are especially desirable in such applications. This can be realized significantly better with a 3D system than with conventional 2D systems. In a 3D system, minimum power consumption can, for example, also be enabled by minimum conductive traces due to the omission of signal drivers.

The materials and/or production technologies needed for non-silicon based neuronal networks are mostly not SMOS compatible. According to the current state of the art, noble metals of all sorts, such as gold, platinum, palladium, but also less noble metals such as molybdenum, copper, titanium or tungsten are used. The production temperatures (up to 800° C.) of the devices needed for emulation of synapses and neurons such as memristors or memtransistors are partly above the maximum allowable temperature of ready-processed CMOS circuits (up to 450° C.). Thus, production separate from CMOS processing is needed. However, the spatial proximity of the neuronal devices or networks to the CMOS or analog chips is advantageous, since the signals also have to be processed further or rendered.

The approaches so far are merely within the framework of CMOS technologies using silicon as semiconductor. Currently, the applicant does not know of any solution for the above-described associated problem. In conventional technology, the silicon structures are structured perpendicularly (FinFETs with silicon technology) in order to enable the small footprint, but also to use the so-called fully depletion as electronic effect. In FinFETs, first, fins are etched into a silicon substrate, and subsequently a heavily doped polysilicon is deposited on the fins by means of an LPCVD process. This results in a three-dimensional structure results, which can be used, for example, as a transistor. Further integration of this three-dimensional structure into a 3D system takes place by means of vias that are indirectly connected to the doped region of a device via separate metal conductor trace planes of the chip.

Due to its electric characteristic, monocrystalline silicon would be advantageous compared to polycrystalline silicon. However, in process control, for depositing monocrystalline silicon, the temperature would have to be increased up to the melting temperature of silicon, which would inevitably have the effect that underlying component structures, and, in particular, structures produced in the CMOS technology would be irreparably damaged.

### SUMMARY

According to an embodiment, a semiconductor device structure may have: a substrate with a first main surface located on a first substrate side and a second main surface located on an opposite substrate side, a vertical via extending completely through the substrate between the first main surface and the second main surface, a metallization layer arranged on the first substrate side in the region of the via, which is connected galvanically to the via and a compound semiconductor layer arranged on the metallization layer and connected galvanically to the metallization layer.

Another embodiment may have a three-dimensional electronic semiconductor device having at least one inventive semiconductor device structure, wherein the semiconductor device structure is connected galvanically and/or mechanically to an additional separate electronic device structure by means of the vertical via and wherein the semiconductor device structure and the additional separate electronic device structure are arranged vertically on top of one another.

According to another embodiment, a method for producing a semiconductor device structure may have the steps of: providing a substrate with a first main surface located on a first substrate side and a second main surface located on an opposite second substrate side, structuring a vertical via extending completely through the substrate between the first main surface and the second main surface, arranging a metallization layer on the first substrate side in the region of the via, such that the metallization layer is connected galvanically to the via and arranging a compound semiconductor layer on the metallization layer, such that the compound semiconductor layer is connected galvanically to the metallization layer.

The inventive semiconductor device structure comprises a substrate having a first main surface located on a first substrate side and a second main surface located on an opposite second substrate side. A planar layer stack may be arranged at the first main surface. The substrate can, for example, be a conductive substrate, a non-conductive substrate or a semi-conductive substrate and can comprise, for example, silicon, glass or quartz. The substrate comprises a vertical via extending completely through the substrate between the first main surface and the second main surface. The planar layer stack comprises a metallization layer being arranged in the region of the via on the first substrate side, and being galvanically connected to the via. Further, the planar layer stack comprises a compound semiconductor layer arranged on the metallization layer and connected galvanically to the metallization layer. The compound semiconductor layer comprises at least one compound semiconductor arranged on the metallization layer and connected galvanically to the metallization layer. The compound semiconductor layer can be arranged directly and immediately on the metallization layer. The metallization layer and the compound semiconductor layer arranged above or on the same form a horizontal or planar layer stack on the first main surface of the substrate, wherein the individual layers of the layer stack can extend horizontally and essentially parallel to the first and second main surface of the substrate, respectively. In conventional technology, such semiconductor device structures are mainly produced in silicon technology, i.e. elemental semiconductors and no compound semiconductors are used. In the case of silicon, currently, at most polycrystalline silicon can be deposited on the metallization layer, since for generating monocrystalline silicon, heating above the melting temperature of silicon would have to take place during process control, which would, however, result in the destruction of the underlying layers, such as the metallization layer. However, in the inventive generation of the layer stack with a compound semiconductor, the metallization layer remains intact. Above that, the compound semiconductor can comprise a direct band gap, while elemental semiconductors, such as silicon mostly comprise an indirect band gap. The direct band gap results in significantly better electric characteristics of the semiconductor which is why the inventive compound semiconductor is advantageous compared to the elemental semiconductors (e.g. silicon) used so far.

According to an embodiment, the compound semiconductor layer can comprise a monocrystalline compound semiconductor. Compared to polycrystalline structures, monocrystalline compound semiconductors have particularly good electrical characteristics. Therefore, in the conventional silicon-based methods, the usage of monocrystalline silicon is advantageous. However, as mentioned above, due to the available processes, at most polycrystalline silicon can be deposited directly on a metallization layer so that the same is not irreparably damaged. The invention described herein enables deposition of monocrystalline compound semiconductor material directly on the metallization layer. Monocrystals of more or less complex chemical compounds are also part of monocrystalline compound semiconductor material.

According to a further embodiment, the compound semiconductor layer can comprise at least one 2D composite material. A 2D composite material is not to be mixed up with the 2D systems also described herein. 2D materials, sometimes also referred to as single layer or monolayer materials, are crystalline materials merely comprising a single atomic layer. Several of these monolayers can be stacked on top of each other. 2D materials have the characteristic that the same are deposited or implemented in a monocrystalline manner. Due to unusual characteristics, the same are the subject of extensive (fundamental) research. Generally, 2D materials can either be considered as two-dimensional allotropes of different elements or as compounds of different elements with covalent bond, so-called 2D composite materials. A known representative of an allotropic 2D material is, for example, graphene. As non-limiting and non-exhaustive examples for 2D composite materials, graphene, boronitrene, germanium phosphide and molybdenum (IV) sulfide can be stated. In the following, in particular the compounds of different elements, i.e., 2D composite materials and here in particular compound semiconductors will be considered. The efficient integration of 2D materials in 3D systems is still an extreme challenge as well as a limiting factor in the overall performance of the system and in the circuit design.

According to a further embodiment, the compound semiconductor layer can comprise at least one material of the group of the transition metal dichalcogenides. This means the compound semiconductor layer can comprise an element combination of the group of transition metals and the groupf of chalcogenides. Transition metal dichalcogenides are also referred to as TMDs. TMDs are normally structured of three atomic planes and mostly include two different atomic species, namely one metal and two chalcogenides. The transition metal dichalcogenides, also referred to as TMD monolayers are atomic thin semiconductors of type MX₂, wherein M refers to a transition metal atom (e.g., Mo, W, etc.) and X refers to a chalcogenide atom (e.g., S, Se or Te). Here, normally, one layer of M atoms is arranged between two layers of X atoms. These arrangements are part of the superordinate group of 2D materials. TMD monolayers, such as MoS₂, WS₂, MoSe₂, WSe₂, MoTe₂ have a direct band gap which characterizes them for the usage as compound semiconductors in the inventive compound semiconductor layer.

According to a further embodiment, the compound semiconductor layer can comprise molybdenum disulfide MoS₂. Due to its electrical characteristics, molybdenum disulfide is particularly well suited as compound semiconductor in the inventive compound semiconductor layer. Additionally, an MoS₂ monolayer has a thickness of just 6.5 Å.

According to a further embodiment, the metallization layer can be arranged directly on the first main surface of the substrate. This is, for example, suitable when the substrate has no electrically conductive characteristics. Alternatively, i.e., when the substrate has electrically conductive characteristics, an electrically insulated layer can be arranged on the first substrate side between the first main surface of the substrate and the metallization layer.

According to a further embodiment, the compound semiconductor layer can be arranged on the metallization layer by means of deposition. Here, the compound semiconductor layer can be deposited directly on the metallization layer. Depositing the compound semiconductor material presents a simple and relatively cost-effective option for arranging the compound semiconductor layer on the metallization layer.

According to an alternative embodiment, the compound semiconductor layer can be formed of at least part of the metallization layer by means of chemical conversion. Alternatively or additionally, the compound semiconductor layer can be formed of at least part of a further layer (e.g., a further metallization layer) deposited on the metallization layer by means of chemical conversion. Chemical conversion means a novel method differing from the above-mentioned deposition methods. In chemical conversion, parts of an output layer are converted into the compound semiconductor layer by chemical reactions. The metallization layer or a further layer can be used as an output layer. The output layer is a metallization layer and in particular a transition metal layer, such as molybdenum. The same can be converted by means of suitable reaction partners, such as sulfur. In this chemical conversion, at least part of the output layer is transformed into a compound semiconductor layer of a 2D material comprising a TMD monolayer, in this case MoS₂.

According to a further embodiment, the semiconductor device structure can further comprise a second compound semiconductor layer arranged on the compound semiconductor layer and connected galvanically to the compound semiconductor layer. By means of this arrangement, for example, a diode structure can be generated.

According to a further embodiment, the second compound semiconductor layer can comprise at least one 2D composite material. Accordingly, like the above mentioned (first) compound semiconductor layer, the second compound semiconductor layer can comprise, for example, at least one material of the group of transition metal dichalcogenides, and in particular MoS₂.

According to a further embodiment, the semiconductor device structure can further comprise a third compound semiconductor layer arranged on the second compound semiconductor layer and connected galvanically to the second compound semiconductor layer. By means of this arrangement, for example, a transistor structure can be generated.

According to a further embodiment, the third compound semiconductor layer can at least comprise one 2D composite material. Accordingly, like the above mentioned (first) compound semiconductor layer and/or the second compound semiconductor layer, the third compound semiconductor layer can comprise, for example, at least one material of the group of transition metal dichalcogenides and in particular MoS₂.

According to a further embodiment, a contacting portion connected galvanically to the vertical via can be arranged on the first and/or second substrate side, wherein the semiconductor device structure can be connected galvanically and/or mechanically to an additional separate electronic device structure by means of this contacting portion to generate a three-dimensional electronic semiconductor device, wherein the semiconductor device structure and the additional separate electronic device structure are arranged vertically above one another. Thus, with the inventive semiconductor device structure, a three-dimensional electronic semiconductor device (3D system) can be produced by arranging an additional separate electronic device structure opposite to the first and/or second substrate side that is connected mechanically and/or galvanically to the semiconductor device structure, and, in particular, the compound semiconductor layer by means of a contacting portion. The separate electronic device structure can, for example, be a two-dimensional system produced in planar technology or a further inventive semiconductor device structure. The 3D system producible in that manner can be a 3D package or a 3D IC.

The planar layer stack may comprise a planar 2D device, may form a planar 2D device or may be configured as a planar 2D device. Regarding the definition of a 2D-system it is referred to the above parts of the description. The 2D device may provide a functionality that may exceed the sole electrical functionality of conducting charge carriers only. This may differentiate a 2D device from a via, which via provides a sole functionality of conducting charge carriers only.

Further, the invention relates to a method for producing a respective semiconductor device structure. The method includes providing a substrate with a first main surface located on a first substrate side and a second main surface located on an opposite second substrate side, as well as structuring a vertical via extending completely through the substrate between the first main surface and the second main surface. The method further comprises a step of arranging a planar layer stack at the first main surface of the substrate, wherein the step of arranging the planar layer stack may include that a metallization layer is arranged on the first substrate side in the region of the via, such that the metallization layer is connected galvanically to the via and a compound semiconductor layer is arranged on the metallization layer, such that the compound semiconductor layer is connected galvanically to the metallization layer. Regarding the advantages of the method, reference is made to the above statements regarding the respective apparatus.

### BRIEF DESCRIPTION OF THE DRAWINGS

Embodiments of the present invention will be detailed subsequently referring to the appended drawings, in which:

FIG. 1 is a schematic lateral sectional view of a semiconductor device structure according to an embodiment,

FIG. 2 is a schematic lateral sectional view of a 3D semiconductor device that can be generated with the inventive semiconductor device structure according to an embodiment,

FIG. 3 is a schematic block diagram for illustrating individual method steps of a method for producing a vertical compound semiconductor structure according to an embodiment,

FIG. 4A is a schematic lateral sectional view of the connection structure of a semiconductor device structure according to an embodiment, wherein the compound semiconductor layer is deposited on the metallization layer by means of a deposition method,

FIG. 4B is a schematic lateral sectional view of the connection structure of a semiconductor device structure according to an embodiment, wherein the compound semiconductor layer is generated of at least part of the metallization layer by means of chemical conversion and

FIG. 5A-5D are schematic lateral sectional views for illustrating individual method steps for producing an inventive semiconductor device structure according to an embodiment, wherein several compound semiconductor layers are generated of several metallization layers by means of chemical conversion.

### DETAILED DESCRIPTION OF THE INVENTION

In the following, embodiments will be described in more detail with reference to the figures, wherein elements having the same or similar functions are provided with the same reference numbers.

Method steps illustrated in a block diagram and discussed with reference to the same can also be performed in any other as in the shown or described order. Additionally, method steps relating to a specific feature of an apparatus can be interexchanged with exactly this feature of the apparatus, which also applies vice versa.

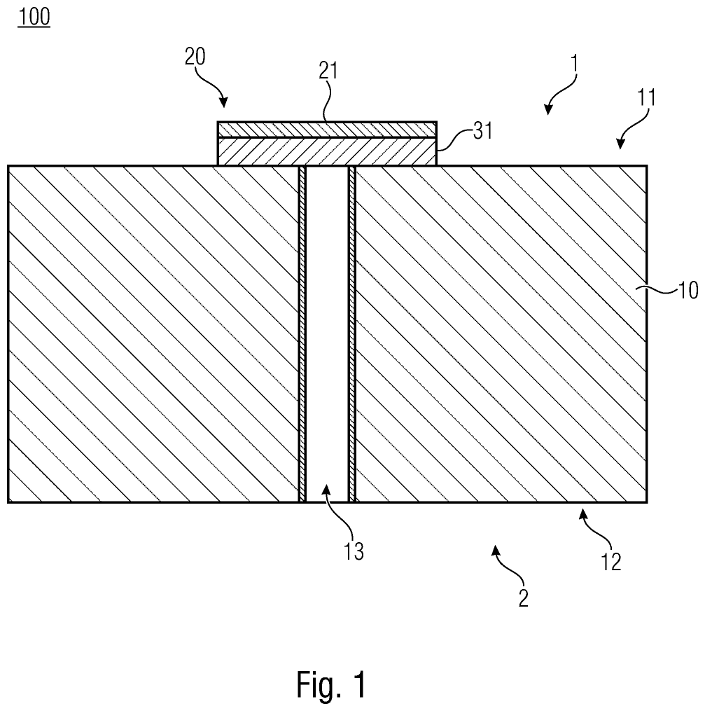

FIG. 1 shows a schematic lateral sectional view of an inventive semiconductor device structure 100. The semiconductor device structure 100 comprises a substrate 10 with a first main surface 11 located on a first substrate side 1 and a second main surface 12 located on an opposite second substrate side 2.

Further, the semiconductor device structure 100 comprises a vertical via 13. The vertical via 13 extends completely through the substrate 10 between the first main surface 11 of the substrate 10 and the second main surface 12 of the substrate 10.

The vertical via 13 can be filled at least partly or completely with an electrically conductive material. This can, for example, be metal and in particular a transition metal.

An electrically conductive layer 31 is arranged on the first substrate side 1 in the region of the vertical via 13. In the region of the vertical via 13 means that the electrically conductive layer 31 at least partly covers the vertical via 13 in a top view. This is advantageous since in that way the signal routing paths between the electrically conductive layer 31 and the vertical via 13 can be kept as short as possible.

The electrically conductive layer 31 can have the same material as the vertical via 13. Additionally, it is possible that the electrically conductive layer 31 is part of the vertical via 13. The vertical via 13 can be filled, for example with electrically conductive material, such as by means of deposition. Here, the electrically conductive material can be deposited at least partly also on the first substrate side 1 in the region of the vertical via 13, such that the material deposited on the first substrate side 1 forms the electrically conductive layer 31. This means the electrically conductive layer 31 would be formed of the material of the vertical via 13 and hence be part of the vertical via 13. In other words, accordingly, the vertical via 13 and the electrically conductive layer 31 can be integrally formed.

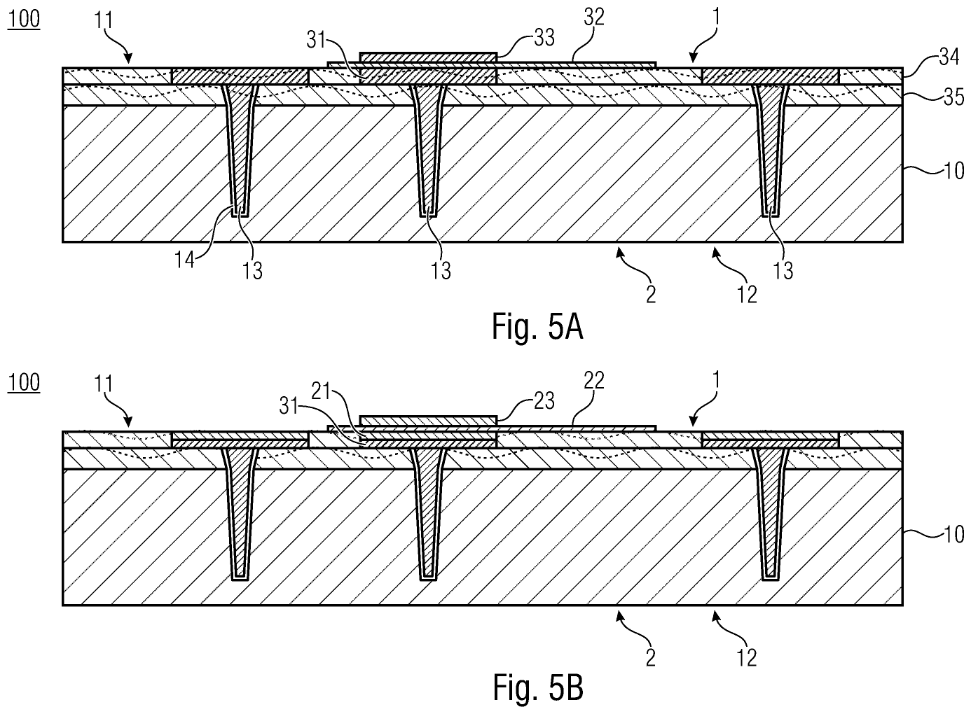

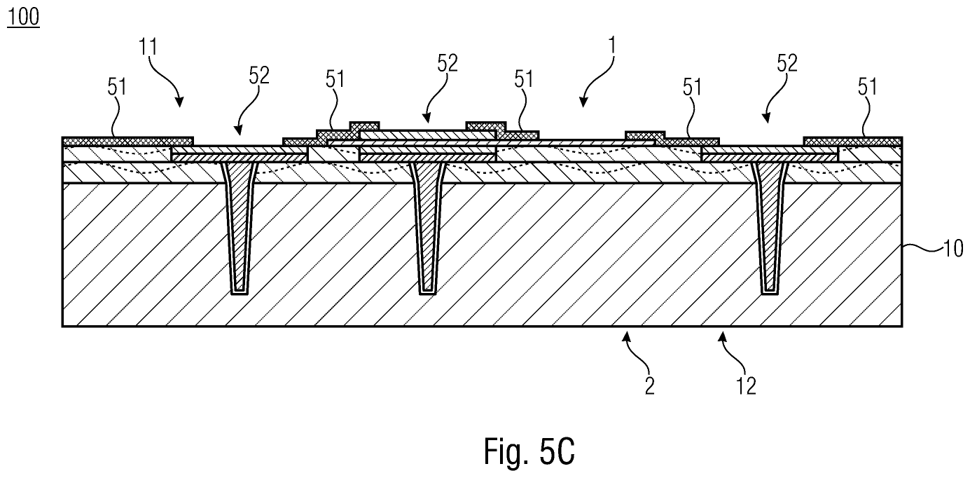

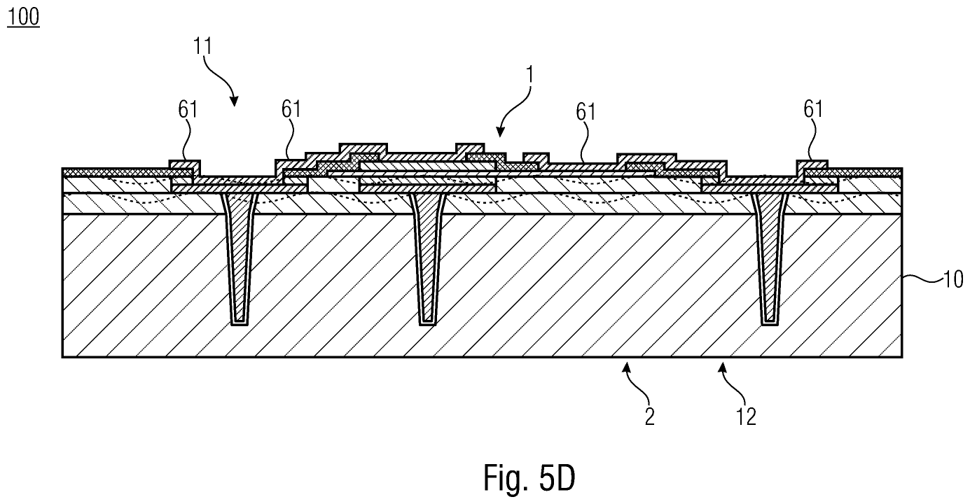

In the embodiment shown herein, the electrically conductive layer 31 can be arranged directly and immediately on the first main surface 11 of the substrate 10. In other embodiments (e.g. FIGS. 5A-5D), an additional electrically insulating layer 35 can be arranged between the first main surface 11 of the substrate 10 and the electrically conductive layer 31. The same applies accordingly for the opposite second substrate side 2 or for the second main surface 12 of the substrate 10.

The electrically conductive layer 31 can, for example, be a metallization layer. Here, a metallization layer is described as a non-limiting example of an electrically conductive layer. The metallization layer 31 arranged on the first substrate side 1 is connected galvanically to the vertical via 13. The metallization layer 31 can comprise, for example, a transition metal.

A compound semiconductor layer 21 is arranged on the metallization layer 31. The compound semiconductor layer 21 can be arranged directly and immediately on the metallization layer 31. It would also be possible that one or several additional layers, and in particular electrically conductive layers are arranged between the compound semiconductor layer 21 and the metallization layer 31. In that case, the compound semiconductor layer 21 would be arranged indirectly above the respective additional layers on the metallization layer 31. The compound semiconductor layer 21 is connected galvanically to the metallization layer 31.

Accordingly, a layer stack 20 can be generated on the first substrate side 1 and on the first main surface 11 of the substrate 10, respectively. In the shown embodiment, the layer stack 20 comprises the metallization layer 31 and the compound semiconductor layer 21. However, it is also possible that the layer stack 20 comprises further additional layers as will be discussed below with reference to the subsequent drawings.

The layer stack 20 can be generated in planar technology. Here, the layers of the layer stack 20 (here: the metallization layer 31 and the compound semiconductor layer 21) can be arranged in a planar or horizontal manner on the first substrate side 1 and on the first main surface 11 of the substrate 10, respectively, and essentially parallel to the first substrate side 1 and the first main surface 11 of the substrate 10, respectively.

The compound semiconductor layer 21 and the metallization layer 31 can have the same layer thickness. However, different layer thicknesses are also possible. For example, the compound semiconductor layer 21 can have a lower layer thickness than the metallization layer 31. This can, among others, be due to the fact that the metallization layer 31 can serve to contact the compound semiconductor layer 21 in an area that is as large as possible and advantageously fully. The compound semiconductor layer 21, on the other hand, can advantageously be configured as monocrystalline 2D material, which merely comprises one or a few (e.g. two to five) individual atomic layers and is hence extremely thin.

According to the invention, the compound semiconductor layer 21 comprises a compound semiconductor arranged on the metallization layer 31 and connected galvanically to the metallization layer 31. By definition, the compound semiconductor is to be distinguished from an elemental semiconductor. While the elemental semiconductor is made up of a single element, e.g. silicon, a compound semiconductor is made up of several elements.

Above that, it is advantageous when the compound semiconductor is monocrystalline. However, for example, the elemental semiconductor silicon cannot be deposited in a monocrystalline manner on the metallization layer, since for this the deposition temperature would have to be increased above the melting temperature of silicon during processing, which would, in practice, result in damages of the surrounding members and components.

Therefore, according to an embodiment, the compound semiconductor layer 21 can comprise a so-called 2D material. For a more accurate definition of the 2D material, reference is made to the paragraphs in the general part of the description above. The 2D material has the characteristic and hence the advantage that the same can be arranged in a monocrystalline manner on the metallization layer 31. Here, the 2D material forms layers that consist, at the molecular level, of individual atomic layers, the so-called monolayers. The 2D material can comprise a single atomic layer or several atomic layers can be combined to a common 2D composite material.

Advantageously, the compound semiconductor layer 21 can comprise at least one material of the group of the transition metal dichalcogenides. This means the compound semiconductor layer 21 can comprise an element combination of the group of transition metals and the group of chalcogenides. For example, the compound semiconductor layer 21 can comprise a 2D composite material having at least one material of the group of the transition metal dichalcogenides, for example with an element combination of the group of transition metals and the group of chalcogenides. Transition metal dichalcogenides or element combinations of the group of transition metals and the group of chalcogenides are atomic thin semiconductors of the type MX₂, wherein M refers to a transition metal atom (e.g. Mo, W, etc.) and X refers to a chalcogenide atom (e.g. S, Se or Te). Here, normally, one layer of M atoms is arranged between two layers of X atoms. These are, for example MoS₂, WS₂, MoSe₂, WSe₂, MoTe₂.

The inventive semiconductor device structure 100 can advantageously be used for structuring 3D systems (e.g. 3D ICs, 3D packages). In 3D systems, several device structures, mostly produced in planar technology, are arranged vertically on top of one another. The inventive semiconductor device structure 100 can represent one of these device structures, wherein an additional separate device structure would be arranged vertically above the semiconductor device structure 100, i.e. opposite to the first substrate side 1 and the first main surface 11 of the substrate 10, respectively, and/or a further additional separate device structure vertically below the semiconductor device structure 100, i.e. opposite to the second substrate side and the second main surface 12 of the substrate 10, respectively. Thus, a 3D system having several device structures arranged vertically on top of one another can be formed, wherein the individual device structures can be galvanically and possibly mechanically connected to each other by means of the vertical via 13.

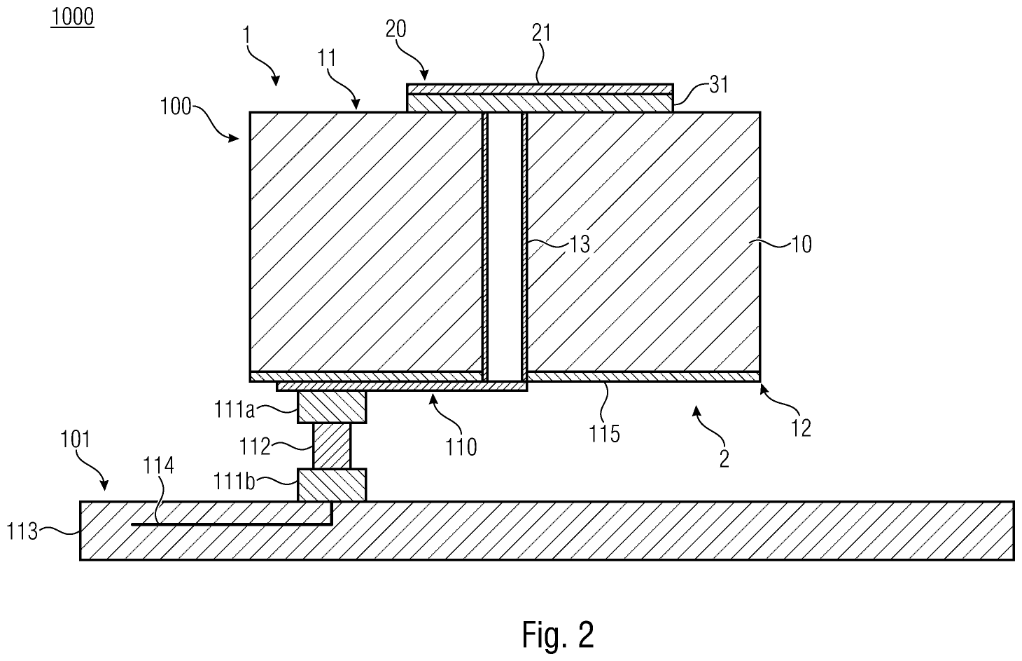

FIG. 2 shows an embodiment of an inventive three-dimensional semiconductor device 1000 having an inventive semiconductor device structure 100 and an additional separate electronic device structure 101. In this embodiment, the additional separate electronic device structure 101 is arranged vertically below the inventive semiconductor device structure 100. This means the additional separate electronic device structure 101 is arranged opposite to the second substrate side 2 and the second main surface 12 of the substrate 10, respectively.

Additionally, in this embodiment, a contacting portion 110 is arranged on the second substrate side 2. The contacting portion 110 can comprise electrically conductive material. As shown, the contacting portion 110 can comprise a layer connected galvanically to the vertical via 13. As illustrated in FIG. 2, optionally, an electrically insulating layer 115 can be arranged on the second main surface 12 of the substrate 10 and the contacting portion 110 and the contacting layer 110, respectively, can be arranged on this electrically insulating layer 115. This is advantageous when the substrate 10 has electrically conductive characteristics. Alternatively, the contacting portion 110 can also be arranged directly on the second main surface 12 of the substrate 10, for example, if the substrate 10 itself has no electrically conductive characteristics. Alternatively or additionally, the contacting portion 110 can have a wiring.

By means of this contacting portion 110, the semiconductor device structure 100 is connected galvanically and/or mechanically to the additional separate electronic device structure 101. This connection can be realized, for example, by means of a so-called intermetallic compound (IMC) connecting method. The contacting portion 110 can comprise, for example, one or several metal pads 111a. The additional separate electronic device structure 101 can also comprise one or several metal pads 111b. Contact pads 112 can be arranged between the metal pads 111a, 111b to galvanically and/or mechanically connect the metal pads 111a, 111b to one another. The metal pads 111a, 111b can, for example, comprise copper and the contact pads 112 can, for example, comprise copper and/or tin.

Alternatively or additionally, it would be possible that the additional separate device structure 101 or a further (not shown) additional separate device structure would be arranged opposite to the first main side 1 and the first main surface 11 of the substrate 10, respectively. In this case, a contacting portion could be arranged on the first main surface 11 of the substrate 10 and on an optional electrically insulating layer 105 arranged on the first main surface 11, respectively, and could be connected galvanically to the vertical via 13. This contacting portion could then serve to galvanically contact the device structure (not illustrated) arranged opposite to the first main surface 11 of the substrate 10.

As can be seen in FIG. 2, the additional separate electronic device structure 101 can comprise, for example, a substrate 113 having integrated metallization layers 114. The metallization layers 114 can be connected galvanically to the inventive semiconductor device structure 100 and, in particular, the compound semiconductor 21 by means of the contacting portion 110.

Thus, the contacting portion 110 can be connected galvanically to the vertical via 13. By this arrangement, the shown three-dimensional electronic semiconductor device 1000 can be generated, wherein the compound semiconductor layer 21 can be connected galvanically to the separate electronic device structure 101 via the vertical via 13.

The additional separate electronic device structure 101 shown in FIG. 2 exemplarily located opposite to the second substrate 2 and the second main surface 12 of the substrate 10, respectively, can itself be an inventive semiconductor device structure 100 described herein. Alternatively, the additional separate electronic device structure 101, as shown in FIG. 2, can be a 2D system produced in planar technology. The additional separate electronic device structure 101 can, for example, comprise an IC, which again cooperates with circuit structures of the inventive semiconductor device structure 100 to form a 3D IC. Alternatively, the additional separate electronic device structure 101 can comprise an individual device, for example a chip that forms a 3D package together with the inventive semiconductor device structure 100.

In the embodiment shown in FIG. 2, the contacting portion 110 is arranged on the second substrate side 2 between the substrate 10 and the additional separate electronic device structure 101. Alternatively or additionally, a further additional separate electronic device structure (not shown) can be arranged above the semiconductor device structure 100, i.e. opposite to the first substrate side and the first main surface 11 of the substrate 10, respectively.

As long as an additional separate electronic device structure 101, and above that an (not shown) additional separate electronic device structure would be connected to the inventive semiconductor device structure 100 in the above-described way, the inventive semiconductor device structure 100 would be arranged between these two additional separate electronic device structures, so that, as a result, also a three-dimensional electronic semiconductor device 1000 (e.g. 3D IC or 3D package) is formed.

Further, all features of the additional separate electronic device structure 101 arranged below, i.e. opposite to the second substrate side 2 and the second main surface 12, respectively, discussed with reference to FIG. 2 apply accordingly to an (not shown) additional separate electronic device structure arranged above, i.e. opposite to the first substrate side 1 and the first main surface 11, respectively.

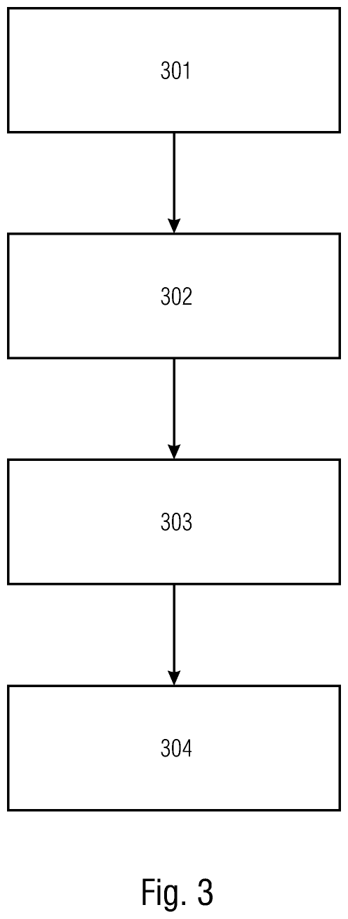

FIG. 3 shows a block diagram of an inventive method for producing a semiconductor device structure 100.

In block 301, a substrate 10 having a first main surface 11 located on a first substrate side 1 and a second main surface 12 located on an opposite second substrate side 12 is provided.

In block 302, a vertical via 13 is structured, wherein the vertical via 13 extends completely through the substrate 10 between the first main surface 11 and the second main surface 12.

In block 303, a metallization layer 31 is arranged on the first substrate side 1 in the region of the via 13, such that the metallization layer 31 is connected galvanically to the via 13.

In block 304, a compound semiconductor layer 21 is arranged on the metallization layer 31, such that the compound semiconductor layer 21 is connected galvanically to the metallization layer 31.

When steps 303 and 304 are performed in the stated order, this results in a layer stack 20, wherein the metallization layer 31 is arranged between the compound semiconductor layer 21 and the substrate 10.

However, steps 303 and 304 can also be performed in reverse order. In this case, a layer stack 20 would result, wherein the compound semiconductor layer 21 is arranged between the metallization layer 31 and the substrate 10.

Generally, it applies that all method steps described herein can also be performed in another order than the one stated.

Inventively, the compound semiconductor layer 21 can be arranged in two different ways on the metallization layer 31. In a first embodiment, the compound semiconductor layer 21 can be deposited on the metallization layer 31. The temperatures for depositing of, for example, monocrystalline 2D materials can be significantly lower than the temperatures for depositing monocrystalline silicon. Thereby, process compatibility can be ensured.

In a second embodiment, the compound semiconductor layer 21 can be formed by means of chemical conversion. For this, part of the metallization layer 31 can be transformed or converted into a compound semiconductor layer 21 by means of suitable reaction partners. The metallization layer 31 can comprise, for example, a material of the group of transition metals, such as molybdenum. A suitable reaction partner for conversion would, for example, be sulfur. Sulfur combines with molybdenum to molybdenum(IV) disulfide MoS₂, which is present directly as monocrystalline 2D composite material or monolayer after conversion.

Alternatively, instead of converting part of the metallization layer 31, a suitable material, such as a metal and in particular a transition metal, can be arranged on the metallization layer 31. Here, again, a material of the group of transition metals can be arranged on the metallization layer 31. With a suitable reaction partner, e.g., sulfur, this additional material layer can be transformed or converted into the compound semiconductor layer 21.

The advantage of chemical conversion compared to deposition is that the respective layer thicknesses of the metallization layer 31 and the compound semiconductor layer 21 can be much lower in chemical conversion than in deposition. During deposition, the compound semiconductor layer 21 is deposited on the metallization layer 31 as additional material, i.e., the overall layer thickness of the layer stack 20 is combined of the layer thickness of the metallization layer 31 plus the layer thickness of the compound semiconductor layer 21 arranged thereon. In chemical conversion, however, the metallization layer 31 is at least partly transformed or converted into the compound semiconductor layer 21. Here, the overall layer thickness of the layer stack 21 is therefore merely made up of the layer thickness of the original metallization layer 31.

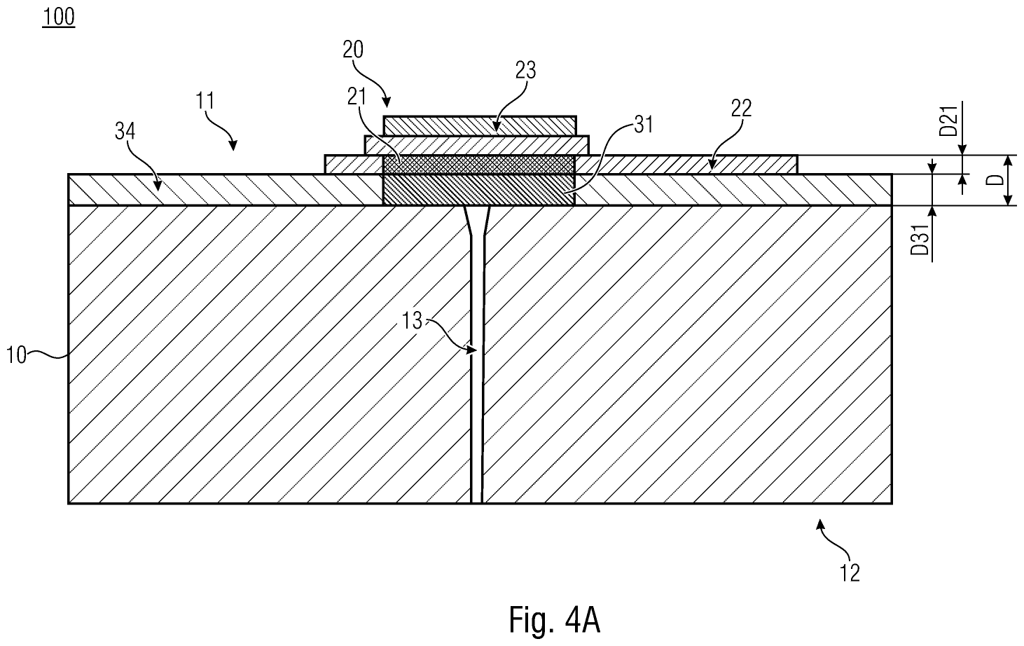

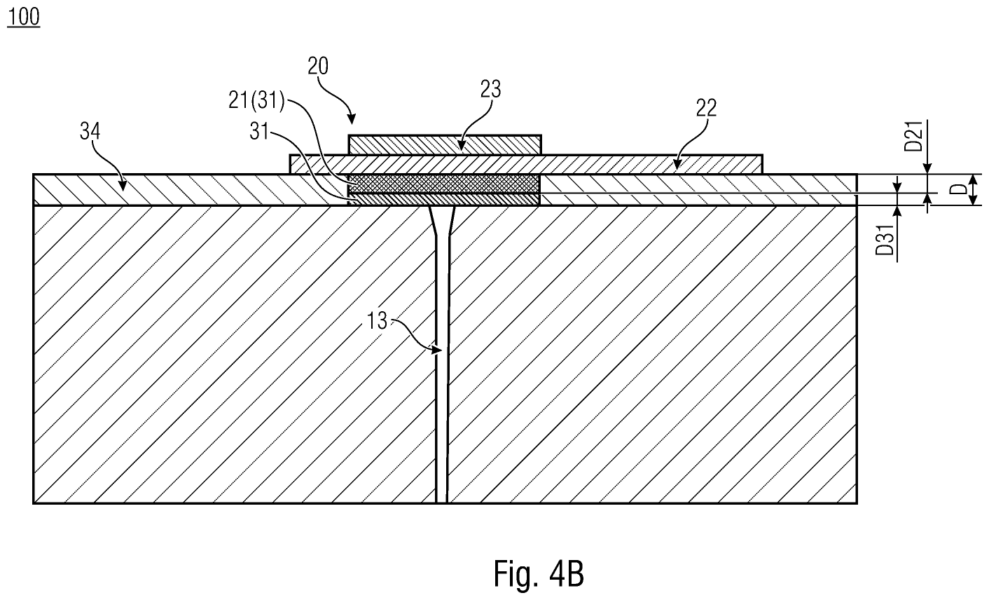

This will be illustrated below with reference to FIGS. 4A and 4B. FIG. 4A shows an embodiment of an inventive semiconductor device structure 100, wherein the compound semiconductor layer 21 has been deposited on the metallization layer 31 by means of a deposition process. FIG. 4B shows an embodiment of an inventive semiconductor device structure 100, wherein the compound semiconductor layer 21 has been formed from at least part of the metallization layer 31 by means of chemical conversion.

In FIGS. 4A and 4B, the horizontal or planar layer stack 20 additionally comprises further layers apart from the metallization layer 31 and the compound semiconductor layer 21 deposited thereon. The layer stack 20 can comprise, for example, a second compound semiconductor layer 22. The second compound semiconductor layer 22 can be arranged on the above-described compound semiconductor layer 21 which can, in a layer stack 20 having several layers, also be referred to as a first compound semiconductor layer 21, and can be connected galvanically to the same.

Here, the second compound semiconductor layer 22 can be arranged on the side of the first compound semiconductor layer 21 opposite to the metallization layer 31, such that the first compound semiconductor layer 21 is arranged between the metallization layer 31 and the second compound semiconductor layer 22. The second compound semiconductor layer 22 can be arranged directly or immediately on the first compound semiconductor layer 21.

The second compound semiconductor layer 22 can also comprise one of the materials described above with reference to the first compound semiconductor layer 21, e.g., a 2D composite material and in particular a material of the group of transition metal dichalcogenides, such as MoS₂. As described above with reference to the first compound semiconductor layer 21, the second compound semiconductor layer 22 can also be arranged on the first compound semiconductor layer 21 by means of deposition or by means of chemical conversion. For chemical conversion, for example, a suitable additional material, such as a metal or a transition metal, can be pre-deposited on the first compound semiconductor layer 21, which can then be transformed or converted into the second compound semiconductor layer 22 by means of chemical conversion.

Further layers are shown in FIGS. 4A and 4B. As long as the layer stack 20 comprises at least the first compound semiconductor layer 21 and the second compound semiconductor layer 22, the inventive semiconductor device structure 100 can be realized as a diode structure.

Further, the horizontal and planar layer stack 20, respectively, can comprise a third compound semiconductor layer 23. The third compound semiconductor layer 23 can be arranged on the above-described second compound semiconductor layer 22 and be connected galvanically to the same.

Here, the third compound semiconductor layer 23 can be arranged on the side of the second compound semiconductor layer 22 opposite to the first compound semiconductor layer 21, such that the second compound semiconductor layer 22 is arranged between the first compound semiconductor layer 21 and the third compound semiconductor layer 23. The third compound semiconductor layer 23 can be arranged directly or immediately on the second compound semiconductor layer 22.

The third compound semiconductor layer 23 can also comprise one of the materials described above with respect to the first compound semiconductor layer 21, e.g., a 2D composite material and in particular a material of the group of transition metal dichalcogenides, such as MoS₂. As descried above with reference to the first compound semiconductor layer 21, the third compound semiconductor layer 23 can also be arranged on the second compound semiconductor layer 22 by means of the deposition or by means of chemical conversion. For chemical conversion, for example, a suitable additional material, such as metal or transition metal can be pre-deposited on the second compound semiconductor layer 22, which can then be transformed or converted into the third compound semiconductor layer 23 by means of chemical conversion.

As long as the layer stack 20 comprises the compound semiconductor layers shown in FIGS. 4A and 4B, i.e. the first compound semiconductor layer 21, the second compound semiconductor layer 22 as well as the third compound semiconductor layer 23, the inventive semiconductor device structure 100 can be realized as a transistor structure.

It is also possible that further layers, for example metallization layers, are arranged between the individual layers 21, 22, 23, 31.

As mentioned above, arranging the compound semiconductor layer 21 on the metallization layer 31 by means of chemical conversion can have the advantage that the overall thickness is thinner than when depositing the compound semiconductor layer 21.

Thus, it can be seen, for example in FIG. 4A, that the compound semiconductor layer 21 is deposited directly on the metallization layer 31. Here, the metallization layer 31 comprises a layer thickness D31 and the compound semiconductor layer 21 comprises a layer thickness D21. Both layers together have an overall layer thickness D made up of the two layer thicknesses D21 and D31.

In FIG. 4B, it can be seen that the compound semiconductor layer 21 is formed of at least part of the metallization layer 31 by means of chemical conversion. The original layer thickness of the metallization layer 31 corresponds to the shown layer thickness D. An upper part, i.e. a portion of the metallization layer 31 facing away from the first substrate 1 and the first main surface 11 of the substrate 10, respectively, had been chemically converted, whereby the compound semiconductor layer 21 was generated. This means part of the metallization layer 31 has been converted into the compound semiconductor layer 21.

Accordingly, the original layer thickness D of the metallization layer 31 is reduced by the layer thickness D21 of the compound semiconductor layer 21. The layer thickness of the metallization layer 31 remaining after chemical conversion is indicated by D31. The overall layer thickness D of the layer stack 20 with the metallization layer 31 and the compound semiconductor layer 21 generated by means of chemical conversion corresponds, accordingly, to the original layer thickness D of the metallization layer 31 and is lower than the overall layer thickness D of the layers 21, 31 shown in FIG. 4A, wherein the compound semiconductor layer 21 has been deposited on the metallization layer 31.

Also, in a direct comparison between FIGS. 4A and 4B, it can be seen that the entire layer stack 20 generated by means of chemical conversion is significantly lower than the layer stack 20 generated by means of deposition.

Optionally, an additional isolator layer 34 (e.g. dielectric) can be arranged on the first substrate side 1. The isolator layer 34 can be arranged, for example, directly on the first main surface 11 of the substrate 10. The isolator layer 34 can electrically insulate the metallization layer 31 laterally in relation to further electrically conductive structures on the substrate 10.

The inventive semiconductor device structure 100 can also comprise more than the shown three compound semiconductor layers 21, 22, 23. For example, a fourth compound semiconductor layer can be arranged on the third compound semiconductor layer 23. In that case, for example, a thyristor structure could be generated. Also, a fifth compound semiconductor layer can be arranged on the fourth compound semiconductor layer. In that case, for example, a memristor structure could be generated.

Additionally, the compound semiconductor layer 21 shown in FIG. 4A and the compound semiconductor layer 21 shown in FIG. 4B can have different materials and different semiconductors, respectively. Additionally, the compound semiconductor layer 21 shown in FIG. 4A can, for example, be formed by means of chemical conversion of a transition metal layer previously deposited on the metallization layer 31. This means a layer, for example a metal layer, and in particular a transition metal layer can be arranged, e.g. deposited, on the metallization layer 31. This previously deposited layer can then be converted or transformed completely or partly into the compound semiconductor layer 21 by means of chemical conversion using suitable reaction partners. As a result, the converted or generated compound semiconductor layer 21 is arranged on the metallization layer 31.

FIGS. 5A to 5D show the production of an inventive semiconductor device structure 100 at different process times, wherein the compound semiconductor layer 21 is, in this example, generated from part of the metallization layer 31 by means of chemical conversion. An above-described deposition of the compound semiconductor layer 21 on the metallization layer 31 would also be possible.

According to this example, the substrate 10 can comprise several vertical vias 13. As long as the substrate 10 has electrically conductive characteristics, the vias 13 can optionally be electrically insulated with respect to the substrate 10 by means of an electrically insulating layer 14. This means the vertical vias 13 can be configured as vertical vias electrically insulated with respect to the substrate 10. Further, optionally, an electrically insulating cover layer 31 can be arranged on the first substrate side 1, for example directly on the first main surface 11 of the substrate 10, wherein the vias 13 can extend through this electrically insulating lid layer 35. The electrically insulating lid layer 35 can, for example, be a planarized dielectric.

A metallization layer 31 can be arranged on the first substrate side 31 in the region of the via 13 and can be connected galvanically to the respective via 13. For example, as described in the figures above, the metallization layer 31 can be arranged directly on the first main surface 11 of the substrate 10 or the metallization layer 31 can be arranged on the electrically insulating lid layer 35 if present, as shown in FIGS. 5A-5D.

An isolator layer 34 that can electrically insulate the metallization layer 31 laterally with respect to further electrically conductive structures on the substrate 10 can optionally be arranged on the first substrate side 1, for example, directly on the first main surface 11 of the substrate 10, or, if present, on the electrically insulating lid layer 35. The isolator layer 34 can, for example, be a planarized dielectric.

A further layer, for example, a second metallization layer 32, can be arranged on the metallization layer 31. A further layer, for example, a third metallization layer 33, can be again arranged on the second metallization layer 32. In each embodiment of the invention, the metallization layers 31, 32, 33 can comprise at least one transition metal or can be configured as transition metal layers.

As can be seen in FIG. 5B, the metallization layers 31, 32, 33 can be converted at least partly into compound semiconductor layers 21, 22, 23 by means of chemical conversion. For example, an upper portion of the first metallization layer 31 facing away from the substrate 10 can be converted or transformed into the first compound semiconductor layer 21 by means of chemical conversion as described above with reference to FIG. 4B. The second metallization layer 32 can be converted or transformed completely or partly into the second compound semiconductor layer 22 by means of chemical conversion. The third metallization layer 33 can be converted or transformed completely or partly into the third compound semiconductor layer 23 by means of chemical conversion. The individual layers can all be chemically converted in a common step, i.e. first all metallization layers 31, 32, 33 are arranged on top of one another and subsequently the metallization layers 31, 32, 33 are chemically converted together, e.g. by simultaneously adding a suitable reaction partner for chemical conversion.

The result is the inventive semiconductor device structure 100 comprising at least one metallization layer 31 and a compound semiconductor layer 21 arranged thereon shown in FIG. 5B.

The areas of the first metallization layer 31 that are arranged on surrounding vias 13 can also be converted or transformed completely or partly into a compound semiconductor layer by means of chemical conversion.

As can be seen in FIG. 5C, optionally, one or several passivation layers 51 can be arranged on the first substrate side 1. The passivation layers 51 can comprise openings 52 in the area of the respective layers 21, 22, 23, 31 arranged above the vias 13.

As can be seen in FIG. 5D, one or several connection metallization layers 61 can be arranged on the first substrate side 1, and in particular in the area of the above-mentioned openings 52.

Additionally, the substrate 10 can be back-thinned from the rear, i.e. from the second substrate side 2 and the second main surface 12, respectively, until the vertical vias 13 are exposed. In that way, the shown semiconductor device structure 100 can be integrated in a 3D system in that the compound semiconductor layer 21 is connected to an additional separate device structure (not shown) arranged opposite to the second main surface 12 via the vertical via 13.

In the shown arrangement, the device semiconductor structure 100 can form a transistor structure. Here, the three compound semiconductor layers 21, 22, 23 arranged on top of one another can form three alternating p-n junctions realizing the transistor structure. Depending on the connection type, the first compound semiconductor layer 21 can provide an emitter layer of the transistor. The second compound semiconductor layer 22 can provide a base layer of the transistor. And the third compound semiconductor layer 23 can provide a collector layer of the transistor. The emitter layer and the collector layer can also be exchanged. Normally, the emitter layer will have a higher charge carrier density than the base layer and the base layer will again have a higher charge carrier density than the collector layer.

The above statements apply in the case of the transistor structure having three compound semiconductor layers 21, 22, 23 shown in FIG. 5A-5D. As long as the inventive device semiconductor structure is configured as a diode structure comprising two compound semiconductor layers 21, 22, the above applies accordingly.

Although the above aspects have been described in the context of the inventive semiconductor device structure 100, it is obvious that these aspects also represent a description of the respective method for producing an inventive semiconductor device structure 100, such that a block or device of an apparatus can also be regarded as a respective method step or as a feature of a method step. Analogously, aspects described in the context of or as a method step also represent a description of a respective block or detail or feature of a respective apparatus.

In the following, the invention will be summarized again briefly in other words:

The present invention relates, among others, to a method for producing three-dimensional electronic systems 1000 and in particular three-dimensional integrated circuits. Three-dimensional integration means the vertical connection (mechanical and electrical) of devices. The advantages of a three-dimensional integrated electronic system 1000 are, among others, the higher packing densities and switching velocities (due to shorter conduction paths) that can be obtained compared to two-dimensional systems (planar technology).

The inventive semiconductor device structure 100 realizes a shortest possible connection within a 3D system 1000 between monocrystalline (2D) semiconductor material and electric contact to the next subsystem 101. This can be particularly advantageous for the vertical structure of electronic devices with minimum footprint and minimum power consumption for neuromorphic networks, for example for a 3D system structure for low-loss neuronal networks.

For this, it is suggested according to the invention to generate an electrically insulated via 13 through the substrate 10 (through substrate via; TSV) that is in direct contact with the semiconductive structure 21. The TSV 13 can be generated first. The semiconductive layer 21 can either be deposited on the TSV 13 and structured or can be locally generated by direct chemical reaction. By means of further depositions or chemical conversions, more complex semiconductor devices including at least one TSV 13 result. Between the TSV metal and the semiconductive layers 21, 22, 23 of the device 100, other metals or semiconductive layers can be introduced as buffer layers for adapting the contact resistance. This offers a shortest possible connection between a semiconductor 21 and TSV 13 as well as the target chip of the 3D system 1000.

Embodiments of the invention form a microelectronic connection to a substrate via 13 and compound semiconductor structure 21.

According to an aspect of the invention, a method for connecting at least two electrical components is suggested, comprising the steps of:

providing a substrate 10,

generating a conductive channel 13 through the substrate 10 electrically insulated with respect to the substrate 10,

generating a contact element 31 connected to the conductive channel 13 in an electrically conductive manner,

generating a first compound semiconductor layer 21 connected to the contact element 31 in an electrically conductive manner,

generating a second compound semiconductor layer 22 connected to the first compound semiconductor layer 21 in an electrically conductive manner and

generating a third compound semiconductor layer 23 connected to the second compound semiconductor layer 22 in an electrically conductive manner.

According to a further aspect, at least one of the compound semiconductor layers 21, 22, 23 is generated by deposition.

According to a further aspect, at least one of the compound semiconductor layers 21, 22, 23 is generated locally by chemical reaction.

FIGS. 5A-5D show a layer sequence and a course for producing TSV 13 in contact with semiconductive layers 21 at the example of local chemical conversion for producing a transistor structure.

Further, a semiconductor device structure 100, also referred to as microelectronic connection device below, is suggested, comprising:

a substrate 10,

a channel 13 through the substrate 10 that is electrically insulated with respect to the substrate 10,

a contact element 31 connected to the conductive channel 13 in an electrically conductive manner,

a first compound semiconductor layer 21 connected to the contact element 31 in an electrically conductive manner,

a second compound semiconductor layer 22 connected to the first compound semiconductor layer 21 in an electrically conductive manner and

a third compound semiconductor layer 23 connected to the second compound semiconductor layer 22 in an electrically conductive manner.

The invention may further be realized by the following embodiments:
1. Semiconductor device structure (100), comprising:
   a substrate (10) with a first main surface (11) located on a first substrate side (1) and a second main surface (12) located on an opposite substrate side (2),
   a vertical via (13) extending completely through the substrate (10) between the first main surface (11) and the second main surface (12),
   a metallization layer (31) arranged on the first substrate side (1) in the region of the via (13), which is connected galvanically to the via (13) and
   a compound semiconductor layer (21) arranged on the metallization layer (31) and connected galvanically to the metallization layer (31).
2. Semiconductor device structure (100) according to embodiment 1,
   wherein the compound semiconductor layer (21) comprises a monocrystalline compound semiconductor.
3. Semiconductor device structure (100) according to embodiment 1 or 2,
   wherein the compound semiconductor layer (21) comprises at least one 2D composite material.
4. Semiconductor device structure (100) according to one of the preceding embodiments,
   wherein the compound semiconductor layer (21) comprises an element combination of the group of transition metals and the group of chalcogenides.
5. Semiconductor device structure (100) according to one of the preceding embodiments,
   wherein the metallization layer (31) is arranged directly on the first main surface (11) of the substrate (10) or
   wherein an electrically insulating layer (35) is arranged on the first substrate side (1) between the first main surface (11) of the substrate (10) and the metallization layer (31).
6. Semiconductor device structure (100) according to one of the preceding embodiments,
   wherein the compound semiconductor layer (21) is arranged on the metallization layer (31) by means of deposition.
7. Semiconductor device structure (100) according to one of embodiments 1 to 5,
   wherein the compound semiconductor layer (21) is formed of at least part of the metallization layer (31) by means of chemical conversion.
8. Semiconductor device structure (100) according to one of the preceding embodiments,
   further comprising a second compound semiconductor layer (22) arranged on the compound semiconductor layer (21) and connected galvanically to the compound semiconductor layer (21).
9. Semiconductor device structure (100) according to embodiment 8,
   wherein the second compound semiconductor layer (22) comprises at least one 2D composite material.
10. Semiconductor device structure (100) according to embodiment 8 or 9,
   further comprising a third compound semiconductor layer (23) arranged on the second compound semiconductor layer (22) and connected galvanically to the second compound semiconductor layer (22).
11. Semiconductor device structure (100) according to embodiment 10,
   wherein the third compound semiconductor layer (23) comprises at least one 2D composite material.
12. Semiconductor device structure (100) according to one of the preceding embodiments,
   wherein a contacting portion (110) connected galvanically to the vertical via (13) is arranged on the first and/or the second substrate side (1, 2), and
   wherein the semiconductor device structure (100) can be connected galvanically and/or mechanically to an additional separate electronic device structure (101) by means of this contacting portion (110) to generate a three-dimensional electronic semiconductor device (1000), wherein the semiconductor device structure (100) and the additional separate electronic device structure (101) are arranged vertically on top of one another.
13. Three-dimensional electronic semiconductor device (1000) having at least one semiconductor device structure (100) according to one of the preceding embodiments,
   wherein the semiconductor device structure (100) is connected galvanically and/or mechanically to an additional separate electronic device structure (101) by means of the vertical via (13) and
   wherein the semiconductor device structure (100) and the additional separate electronic device structure (101) are arranged vertically on top of one another.
14. Method for producing a semiconductor device structure (100), the method comprising the following steps:
   providing a substrate (10) with a first main surface (12) located on a first substrate side (1) and a second main surface (12) located on an opposite second substrate side (2),
   structuring a vertical via (13) extending completely through the substrate (10) between the first main surface (11) and the second main surface (12),
   arranging a metallization layer (31) on the first substrate side (1) in the region of the via (13), such that the metallization layer (31) is connected galvanically to the via (13) and
   arranging a compound semiconductor layer (21) on the metallization layer (31), such that the compound semiconductor layer (21) is connected galvanically to the metallization layer (31).
15. Method according to embodiment 14,
   wherein the step of arranging the compound semiconductor layer (21) includes a monocrystalline compound semiconductor being arranged on the metallization layer (31).
16. Method according to embodiment 14 or 15,
   wherein the step of arranging the compound semiconductor layer (21) includes at least one 2D composite material being arranged on the metallization layer (31).
17. Method according to one of embodiments 14 to 16,
   wherein the step of arranging the compound semiconductor layer (21) includes at least one element combination of the group of transition metals and the group of chalcogenides being arranged on the metallization layer (31).
18. Method according to one of embodiments 14 to 17,
   wherein the metallization layer (31) is arranged directly on the first main surface (11) of the substrate (10) or
   wherein an electrically insulating layer (35) is arranged on the first substrate side (1) between the first main surface (11) of the substrate (10) and the metallization layer (31).
19. Method according to one of embodiments 14 to 18,
   wherein the step of arranging the compound semiconductor layer (21) includes the compound semiconductor layer (21) being deposited by applying a deposition method on the metallization layer (31).
20. Method according to one of embodiments 14 to 18,
   wherein the step of arranging the compound semiconductor layer (21) includes the compound semiconductor layer (21) being formed of at least part of the metallization layer (31) by means of chemical conversion.
21. Method according to one of embodiments 14 to 20,
   wherein a second compound semiconductor layer (22) is arranged on the compound semiconductor layer (21) and connected galvanically to the compound semiconductor layer (21).
22. Method according to embodiment 21,
   wherein the second compound semiconductor layer (22) comprises at least one 2D composite material.
23. Method according to embodiment 21 or 22,
   wherein a third compound semiconductor layer (23) is arranged on the second compound semiconductor layer (22) and connected galvanically to the second compound semiconductor layer (22).
24. Method according to embodiment 23,
   wherein the third compound semiconductor layer (23) comprises at least one 2D composite material.
25. Method according to one of the preceding embodiments, further comprising:
   arranging a contacting portion (110) on the second main surface (12) of the substrate (10) such that the contacting portion (110) is connected galvanically to the vertical via (13) and
      galvanically connecting the semiconductor device structure (100) to an additional separate electronic device structure (101) by means of this contacting portion (110) to generate a three-dimensional electronic semiconductor device, wherein the additional separate electronic device structure (101) is arranged opposite to the second main surface (12) of the substrate (10).

While this invention has been described in terms of several advantageous embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. Semiconductor device structure, comprising:
a substrate with a first main surface located on a first substrate side and a second main surface located on an opposite substrate side, wherein a planar layer stack is arranged at the first main surface,
a vertical via extending completely through the substrate between the first main surface and the second main surface,
wherein the planar layer stack comprises:
a metallization layer arranged on the first substrate side in the region of the via, which is connected galvanically to the via, and
a compound semiconductor layer arranged on the metallization layer and connected galvanically to the metallization layer.

2. Semiconductor device structure according to claim 1,
wherein the compound semiconductor layer comprises a monocrystalline compound semiconductor, and/or
wherein the compound semiconductor layer comprises an element combination of the group of transition metals and the group of chalcogenides.

3. Semiconductor device structure according to claim 1,
wherein the metallization layer is arranged directly on the first main surface of the substrate, or
wherein an electrically insulating layer is arranged on the first substrate side between the first main surface of the substrate and the metallization layer.

4. Semiconductor device structure according to claim 1,
wherein the compound semiconductor layer is arranged on the metallization layer by means of deposition, or
wherein the compound semiconductor layer is formed of at least part of the metallization layer by means of chemical conversion.

5. Semiconductor device structure according to claim 1,
wherein the planar layer stack further comprises a second compound semiconductor layer arranged on the compound semiconductor layer and connected galvanically to the compound semiconductor layer.

6. Semiconductor device structure according to claim 5,
wherein the planar layer stack further comprises a third compound semiconductor layer arranged on the second compound semiconductor layer and connected galvanically to the second compound semiconductor layer.

7. Semiconductor device structure according to claim 1,
wherein at least one of the compound semiconductor layer, the second compound semiconductor layer and the third compound semiconductor layer comprises at least one 2D composite material.

8. Semiconductor device structure according to claim 1,
wherein a contacting portion connected galvanically to the vertical via is arranged on the first and/or the second substrate side, and
wherein the semiconductor device structure can be connected galvanically and/or mechanically to an additional separate electronic device structure by means of this contacting portion to generate a three-dimensional electronic semiconductor device, wherein the semiconductor device structure and the additional separate electronic device structure are arranged vertically on top of one another.

9. Semiconductor device structure according to claim 1,
wherein the planar layer stack forms a planar 2D-device.

10. Three-dimensional electronic semiconductor device having at least one semiconductor device structure according to claim 1,
wherein the semiconductor device structure is connected galvanically and/or mechanically to an additional separate electronic device structure by means of the vertical via and
wherein the semiconductor device structure and the additional separate electronic device structure are arranged vertically on top of one another.

11. Method for producing a semiconductor device structure, the method comprising the following steps:
providing a substrate with a first main surface located on a first substrate side and a second main surface located on an opposite second substrate side,
arranging a planar layer stack at the first main surface of the substrate,
structuring a vertical via extending completely through the substrate between the first main surface and the second main surface,
wherein the step of arranging the planar layer stack comprises:
arranging a metallization layer on the first substrate side in the region of the via, such that the metallization layer is connected galvanically to the via, and
arranging a compound semiconductor layer on the metallization layer, such that the compound semiconductor layer is connected galvanically to the metallization layer.

12. Method according to claim 11,
wherein the step of arranging the compound semiconductor layer includes a monocrystalline compound semiconductor being arranged on the metallization layer, or
wherein the step of arranging the compound semiconductor layer includes at least one element combination of the group of transition metals and the group of chalcogenides being arranged on the metallization layer.

13. Method according to claim 11,
wherein the step of arranging the compound semiconductor layer includes the compound semiconductor layer being deposited by applying a deposition method on the metallization layer, or
wherein the step of arranging the compound semiconductor layer includes the compound semiconductor layer being formed of at least part of the metallization layer by means of chemical conversion.

14. Method according to claim 11,
wherein the step of arranging the planar layer stack comprises a step of arranging a second compound semiconductor layer on the compound semiconductor layer and connecting it galvanically to the compound semiconductor layer.

15. Method according to claim 14,
wherein the step of arranging the planar layer stack comprises a step of arranging a third compound semiconductor layer on the second compound semiconductor layer and connecting the third compound semiconductor layer galvanically to the second compound semiconductor layer.
